(19) United States
(12) Patent Application Publication
(10) Pub. No.: US 2026/0362752 A1
(43) Pub. Date: Nov. 12, 2026

(54) SEMICONDOCTOR DEVICE INCLUDING FERROELECTRIC MATERIAL FILM AND METHOD FOR FABRICATING THE SAME

(71) Applicant: Samsung Electronics Co., Ltd., Suwon-si (KR)

(72) Inventor: Dong Gun Kim, Suwon-si (KR)

(73) Assignee: Samsung Electronics Co., Ltd., Suwon-si (KR)

(21) Appl. No.: 19/467,151

(22) Filed: Feb. 2, 2026

(30) Foreign Application Priority Data
May 7, 2025 (KR) 10-2025-0058862

(51) Int. Cl. H10D 30/69; H10B 12/00; H10B 41/27; H10B 41/41; H10B 43/27; H10B 43/40; H10D 84/85

(52) U.S. Cl. CPC H10D 30/701; H10B 12/30; H10B 12/315; H10B 12/50; H10B 41/27; H10B 41/41; H10B 43/27; H10B 43/40; H10D 84/85

(57) ABSTRACT

A semiconductor device includes a substrate; a ferroelectric material film on the substrate; a gate insulating film on the ferroelectric material film; and a gate electrode film on the gate insulating film, wherein the gate electrode film is in contact with the gate insulating film.

### CROSS-REFERENCE TO RELATED APPLICATIONS

This present application claims priority to and the benefit under 35 U.S.C. § 119(a)-(d) of Korean Patent Application No. 10-2025-0058862, filed on May 7, 2025, in the Korean Intellectual Property Office, the entire disclosure of which is incorporated herein by reference.

### FIELD

The present disclosure relates to a semiconductor device including ferroelectric material film and a method for fabricating the same.

### BACKGROUND

Ferroelectrics are materials having ferroelectricity in which an internal electric dipole moment is aligned to maintain spontaneous polarization even when no electric field is applied from the outside. Even if a certain voltage is applied to the ferroelectrics and then the voltage is returned to OV, the polarization remains semi-permanently in the ferroelectrics. Research for applying such ferroelectrics characteristics to logic elements or memory elements is continued. For example, in the case of a ferroelectrics field effect transistor using the ferroelectrics, a threshold voltage of the field effect transistor may change depending on a polarization direction in the ferroelectrics. A logic element or a memory element may be realized by utilizing the threshold voltage change characteristics of such a ferroelectrics field effect transistor.

### SUMMARY

Aspects of the present disclosure provide a semiconductor device having improved product reliability.

Aspects of the present disclosure provide a method for fabricating a semiconductor device that may fabricate a semiconductor device having improved product reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to aspects of the present disclosure, there is provided a semiconductor device including a substrate; a ferroelectric material film on the substrate; a gate insulating film on the ferroelectric material film; and a gate electrode film on the gate insulating film, wherein the gate electrode film is in contact with the gate insulating film.

According to embodiments of the present disclosure, there is provided a semiconductor device including a substrate including a first region and a second regions different from each other; a first ferroelectric material film on the first region of the substrate; a first gate insulating film on the first ferroelectric material film; a first gate electrode film on the first gate insulating film; a second ferroelectric material film on the second region of the substrate; a second gate insulating film on the second ferroelectric material film; and a second gate electrode film on the second gate insulating film, wherein an upper side of the first gate electrode film is coplanar with an upper side of the second gate electrode film.

According to embodiments of the present disclosure, there is provided a semiconductor device including a memory cell; and a transistor electrically connected to the memory cell, wherein the transistor includes a gate conductive film, a gate insulating film, and one ferroelectric material film, and the one ferroelectric material film is disposed between the gate conductive film and the gate insulating film.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram for explaining a semiconductor device according to some embodiments;

FIGS. 2 to 6 are diagrams for explaining a method for fabricating a semiconductor device according to some embodiments;

FIGS. 7 to 9 are diagrams for explaining a ferroelectric material film formed by the method for fabricating the semiconductor device according to some embodiments;

FIG. 10 is schematic layout diagram of the semiconductor device according to some embodiments;

FIG. 11 is a schematic layout diagram showing an enlarged view of a portion R3 of FIG. 10;

FIG. 12 is a cross-sectional view taken along A-A of FIG. 11;

FIG. 13 is a cross-sectional view taken along B-B of FIG. 11;

FIG. 14 is layout diagram for explaining a semiconductor device according to some embodiments;

FIG. 15 is perspective view for explaining a semiconductor device according to some embodiments;

FIG. 16 is a cross-sectional view taken along C-C and D-D of FIG. 14;

FIG. 17 is layout diagram for explaining the semiconductor device according to some embodiments;

FIG. 18 is perspective view for explaining the semiconductor device according to some embodiments;

FIG. 19 is diagram for explaining the semiconductor device according to some embodiments;

FIG. 20 is diagram for explaining the semiconductor device according to some embodiments; and

FIG. 21 is diagram for explaining the semiconductor device according to some embodiments.

### DETAILED DESCRIPTION

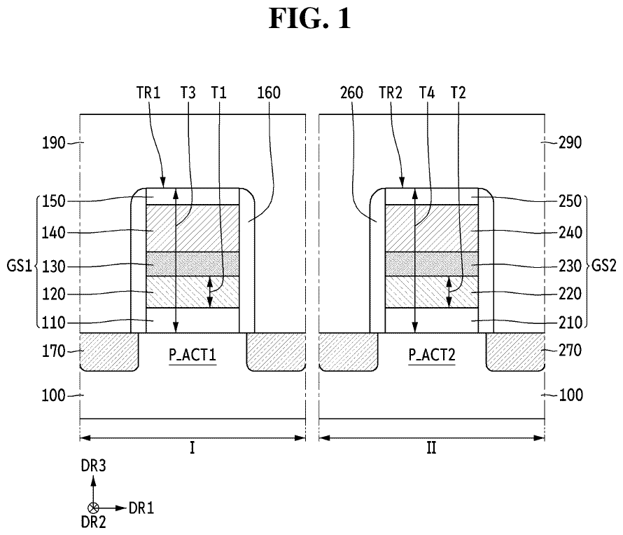

FIG. 1 is diagram for explaining a semiconductor device according to some embodiments.

Referring to FIG. 1, the semiconductor device according to some embodiments may include a first substrate 100, a first transistor TR1, and a second transistor TR2.

The first substrate 100 may include a first region I and a second region II. The first region I and the second region II may be regions spaced apart from each other or may be regions connected to each other.

The first substrate 100 may be a silicon substrate or a silicon-on-insulator (SOI). In contrast, the first substrate 100 may include, but is not limited to, silicon germanium, silicon germanium on insulator (SGOI), indium antimonide, lead telluride, indium arsenide, indium phosphide, gallium arsenide or gallium antimonide.

A peri-element isolation film may be disposed inside the first substrate 100. The peri-element isolation film may be formed as a shallow trench isolation (STI) structure. The peri-element isolation film may extend, for example, in a third direction DR3. The peri-element isolation film may include, for example, at least one of silicon oxide, silicon nitride, silicon oxynitride, and combinations thereof.

The first substrate 100 may include a first peri-active region P_ACT1 and a second peri-active region P_ACT2 that are defined by the peri-element isolation film. For example, the first peri-active region P_ACT1 included in the first region I may be a region in which a PMOS transistor is formed. The second peri-active region P_ACT2 included in the second region II may be a region in which an NMOS transistor is formed.

The first transistor TR1 is disposed in the first region I of the first substrate 100. The first transistor TR1 may include a first gate stack GS1 and a first source/drain region 170. The second transistor TR2 may be disposed in the second region II of the first substrate 100. The second transistor TR2 may include a second gate stack GS2 and a second source/drain region 270.

Hereinafter, the first direction DR1 and the second direction DR2 are directions parallel to an upper side of the first substrate 100 on which the first transistor TR1 and the second transistor TR2 are disposed. The third direction DR3 is a direction perpendicular to the upper side of the first substrate 100. The first to third directions DR1, DR2, and DR3 may intersect each other.

The first gate stack GS1 may include a first interfacial film 110, a first ferroelectric material film 120, a first gate insulating film 130, a first gate electrode film 140, and a first gate capping film 150. The first interfacial film 110, the first ferroelectric material film 120, the first gate insulating film 130, the first gate electrode film 140 and the first gate capping film 150 may be sequentially stacked on the first region I of the first substrate 100 along the third direction DR3. The first gate stack GS1 may include one first ferroelectric material film 120 and one first gate electrode film 140.

The second gate stack GS2 may include a second interfacial film 210, a second ferroelectric material film 220, a second gate insulating film 230, a second gate electrode film 240 and a second gate capping film 250. The second interfacial film 210, the second ferroelectric material film 220, the second gate insulating film 230, the second gate electrode film 240 and the second gate capping film 250 may be sequentially stacked on the second region II of the first substrate 100 along the third direction DR3. The second gate stack GS2 may include one second ferroelectric material film 220 and one second gate electrode film 240. The first gate stack GS1 of the first transistor TR1 may have the same stack structure as the second gate stack GS2 of the second transistor TR2. For example, the first gate stack GS1 may have the same composition, thickness, or the like as the second gate stack GS2.

The first interfacial film 110 may be disposed on the first region I of the first substrate 100. The first interfacial film 110 may be in contact with the first substrate 100. The second interfacial film 210 may be disposed on the second region II of the first substrate 100. The second interfacial film 210 may be in contact with the first substrate 100. Each of the first interfacial film 110 and the second interfacial film 210 may include, for example, silicon oxide.

The first ferroelectric material film 120 may be disposed on the first interfacial film 110. The second ferroelectric material film 220 may be disposed on the second interfacial film 210.

Each of the first ferroelectric material film 120 and the second ferroelectric material film 220 may be a ferroelectric material film having ferroelectrics characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material in which hafnium oxide is doped with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary depending on which ferroelectrics material are included in the ferroelectric material film.

For example, when the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % of aluminum. Here, the ratio of the dopant may be a ratio of aluminum to the sum of hafnium and aluminum.

When the dopant is silicon (Si), the ferroelectric material film may include 2 to 10 atomic % of silicon. When the dopant is yttrium (Y), the ferroelectric material film may include 2 to 10 atomic % of yttrium. When the dopant is gadolinium (Gd), the ferroelectric material film may include 1 to 7 atomic % of gadolinium. When the dopant is zirconium (Zr), the ferroelectric material film may include 50 to 80 atomic % of zirconium.

The ferroelectric material film may have a thickness having ferroelectrics characteristics. The thickness of the ferroelectric material film may be, for example, but is not limited to, 0.5 nm to 10 nm. Since a critical thickness that exhibits ferroelectrics characteristics may be changed for each ferroelectrics material, the thickness of the ferroelectric material film may be changed depending on the ferroelectrics material.

Each of the first ferroelectric material film 120 and the second ferroelectric material film 220 has an orthorhombic crystal structure. The orthorhombic crystal structure may have, for example, a structure belonging to a Pca21 space group.

Twice (2Pᵣ) the remanent polarization (Pr) value of each of the first ferroelectric material film 120 and the second ferroelectric material film 220 may be 40 μC/cm² or more. Twice (2Vc) the coercive voltage (Vc) value of each of the first ferroelectric material film 120 and the second ferroelectric material film 220 may be 5V or more. While the first transistor TR1 is operating, since the first transistor TR1 is not subjected to an electric field equal to or greater than the coercive voltage (Vc) of the first ferroelectric material film 120, a threshold voltage of the first transistor TR1 does not shift. While the second transistor TR2 is operating, since the second transistor TR2 is not subjected to an electric field equal to or greater than the coercive voltage (Vc) of the second ferroelectric material film 220, the threshold voltage of the second transistor TR2 does not shift.

Although the crystal structure of the ferroelectrics material may be checked by scanning transmission electron microscopy (STEM), high-angle annular dark-field scanning transmission electron microscopy (HAADF-STEM), transmission electron microscopy (TEM), grazing incidence X-ray diffraction (GIXRD) and the like, any method used in the present technical field is possible, without being limited thereto.

The first gate insulating film 130 may be disposed on the first ferroelectric material film 120. The first ferroelectric material film 120 may be disposed below the first gate insulating film 130, and may not be disposed above the first gate insulating film 130. The first gate insulating film 130 may be in contact with the first ferroelectric material film 120.

The second gate insulating film 230 may be disposed on the second ferroelectric material film 220. The second ferroelectric material film 220 may be disposed below the second gate insulating film 230, and may not be disposed above the second gate insulating film 230. The second gate insulating film 230 may be in contact with the second ferroelectric material film 220.

Each of the first gate insulating film 130 and the second gate insulating film 230 may include, for example, a high dielectric constant material having a dielectric constant greater than that of silicon oxide. The high dielectric constant material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The first gate electrode film 140 may be disposed on the first gate insulating film 130. The first gate insulating film 130 may be disposed between the first ferroelectric material film 120 and the first gate electrode film 140. The first gate insulating film 130 may be in contact with the first gate electrode film 140.

The second gate electrode film 240 may be disposed on the second gate insulating film 230. The second gate insulating film 230 may be disposed between the second ferroelectric material film 220 and the second gate electrode film 240. The second gate insulating film 230 may be in contact with the second gate electrode film 240.

Each of the first gate electrode film 140 and the second gate electrode film 240 may include at least one of a metal, a conductive metal nitride, a conductive metal carbonitride, a conductive metal carbide, a metal silicide, a doped semiconductor material, a conductive metal oxide, and a conductive metal oxynitride. Each of the first gate electrode film 140 and the second gate electrode film 240 may include, for example, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), impurity-doped silicon, impurity-doped silicon germanium, impurity-doped germanium, and combinations thereof. Each of the conductive metal oxides and conductive metal oxynitrides may include, but is not limited to, an oxidized form of the aforementioned materials.

The first gate capping film 150 may be disposed on the first gate electrode film 140. The second gate capping film 250 may be disposed on the second gate electrode film 240. Each of the first gate capping film 150 and the second gate capping film 250 may include an insulating material, for example, but is not limited to, silicon oxide, silicon oxynitride, silicon nitride, or the like.

The first gate spacer 160 may be disposed on a side wall of the first gate electrode film 140. The first gate spacer 160 may be disposed on both side walls of the first gate stack GS1. The first gate stack GS1 may be disposed between the first gate spacers 160.

The second gate spacer 260 may be disposed on a side wall of the second gate electrode film 240. The second gate spacer 260 may be disposed on both side walls of the second gate stack GS2. The second gate stack GS2 may be disposed between the second gate spacers 260.

Each of the first gate spacer 160 and the second gate spacer 260 may include an insulating material, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), and silicon oxycarbide (SiOC). Although each of the first spacer 160 and the second gate spacer 260 is shown as being a single film, this is only for convenience of explanation, and embodiments are not limited thereto.

The first source/drain region 170 may be disposed on both sides of the first gate stack GS1. The first source/drain region 170 may be formed in the first substrate 100. The second source/drain region 270 may be disposed on both sides of the second gate stack GS2. The second source/drain region 270 may be formed in the first substrate 100.

The first source/drain region 170 may include a P-type impurity. For example, the P-type impurity may include at least one of boron (B) and gallium (Ga). The second source/drain region 270 may include an N-type impurity. For example, the N-type impurity may include at least one of phosphorus (P), arsenic (As), antimony (Sb), and bismuth (Bi).

A third thickness T3 of the first gate stack GS1 in the third direction DR3 may be substantially the same as a fourth thickness T4 of the second gate stack GS2 in the third direction DR3. An upper side of the first gate stack GS1 (an upper side of the first gate capping film 150) may be coplanar with an upper side of the second gate stack GS2 (an upper side of the second gate capping film 250). The upper side of the first gate electrode film 140 and the upper side of the second gate electrode film 240 may be coplanar with each other. A thickness of the first interfacial film 110 in the third direction DR3 may be substantially the same as a thickness of the second interfacial film 210 in the third direction DR3. A first thickness T1 of the first ferroelectric material film 120 in the third direction DR3 may be substantially the same as a second thickness T2 of the second ferroelectric material film 220 in the third direction DR3. The first thickness T1 of the first ferroelectric material film 120 in the third direction DR3 and the second thickness T2 of the second ferroelectric material film 220 in the third direction DR3 may each be 1 nm or more. The thickness of the first gate insulating film 130 in the third direction DR3 may be substantially the same as the thickness of the second gate insulating film 230 in the third direction DR3. The thickness of the first gate electrode film 140 in the third direction DR3 may be substantially the same as the thickness of the second gate electrode film 240 in the third direction DR3. The thickness of the first gate capping film 150 in the third direction DR3 may be substantially the same as the thickness of the second gate capping film 250 in the third direction DR3.

The first interlayer insulating film 190 may be disposed on the first region I of the first substrate 100. The first interlayer insulating film 190 may be disposed on the first transistor TR1. The first interlayer insulating film 190 may cover the first source/drain region 170, the first gate stack GS1 and the first gate spacer 160.

The second interlayer insulating film 290 may be disposed on the second region II of the first substrate 100. The second interlayer insulating film 290 may be disposed on the second transistor TR2. The second interlayer insulating film 290 may cover the second source/drain region 270, the second gate stack GS2, and the second gate spacer 260.

Each of the first interlayer insulating film 190 and the second interlayer insulating film 290 may include at least one of, for example, silicon oxide, silicon nitride, and silicon oxynitride.

The semiconductor device may further include at least one of a first contact penetrating the first interlayer insulating film 190 and connected to the first source/drain region 170, a second contact penetrating the first interlayer insulating film 190 and the first gate capping film 150 and connected to the first gate electrode film 140, a third contact penetrating the second interlayer insulating film 290 and connected to the second source/drain region 270, and a fourth contact penetrating the second interlayer insulating film 290 and the second gate capping film 250 and connected to the second gate electrode film 240. Each of the first to fourth contacts may include, for example, a conductive material.

In the semiconductor device according to some embodiments, since the first transistor TR1 and the second transistor TR2 include the first ferroelectric material film 120 and the second ferroelectric material film 220 having an orthorhombic crystal structure, the capacitance of the first transistor TR1 and the second transistor TR2 may increase.

In the semiconductor device according to some embodiments, the threshold voltage of the transistors TR1 and TR2 may be adjusted through the stacked ferroelectric material films 120 and 220 and the gate insulating films 130 and 230 of the transistors TR1 and TR2.

In the semiconductor device according to some embodiments, the first gate stack GS1 of the first transistor TR1 and the second gate stack GS2 of the second transistor TR2 may have the same height of the upper side. Therefore, there may be no step between the first gate stack GS1 of the first transistor TR1 and the second gate stack GS2 of the second transistor TR2.

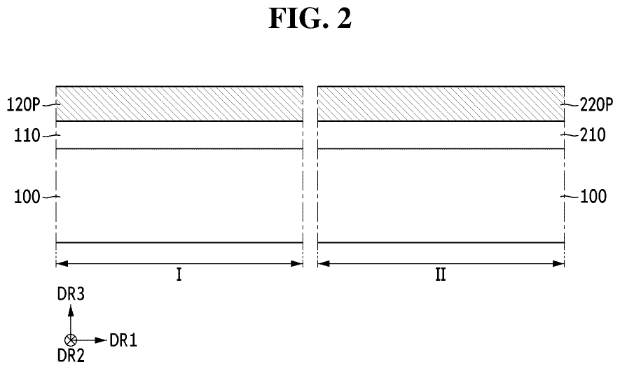

FIGS. 2 to 6 are diagrams for explaining a method for fabricating a semiconductor device according to some embodiments. For convenience of explanation, repeated parts of contents explained above using FIG. 1 will be briefly explained or omitted.

Referring to FIG. 2, the first interfacial film 110 is formed on the first region I of the first substrate 100, and the second interfacial film 210 is formed on the second region II of the first substrate 100. For example, the first interfacial film 110 and the second interfacial film 210 may be formed through the same fabricating process.

Next, a first preliminary ferroelectric material film 120P is formed on the first interfacial film 110, and a second preliminary ferroelectric material film 220P is formed on the second interfacial film 210. The first preliminary ferroelectric material film 120P and the second preliminary ferroelectric material film 220P are ferroelectric material films each including a ferroelectrics material. A thickness of the first preliminary ferroelectric material film 120P in the third direction DR3 may be substantially the same as a thickness of the second preliminary ferroelectric material film 220P in the third direction DR3. The thickness of the first preliminary ferroelectric material film 120P in the third direction DR3 and the thickness of the second preliminary ferroelectric material film 220P in the third direction DR3 may each be 1 nm or more. For example, the first preliminary ferroelectric material film 120P and the second preliminary ferroelectric material film 220P may be formed through the same fabricating process. The first preliminary ferroelectric material film 120P and the second preliminary ferroelectric material film 220P may include the same material and have the same thickness.

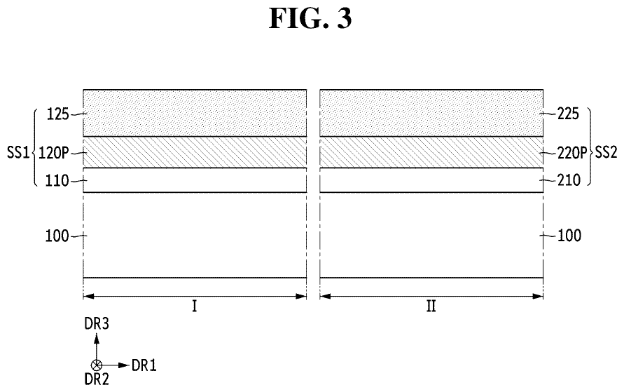

Referring to FIG. 3, a first sacrificial film 125 is formed on the first preliminary ferroelectric material film 120P, and a second sacrificial film 225 is formed on the second preliminary ferroelectric material film 220P. A first stacked stack SS1 including the first interfacial film 110, the first preliminary ferroelectric material film 120P, and the first sacrificial film 125 stacked sequentially is formed on the first region I of the first substrate 100, and a second stacked stack SS2 including the second interfacial film 210, the second preliminary ferroelectric material film 220P, and the second sacrificial film 225 stacked sequentially is formed on the second region II of the first substrate 100. The first sacrificial film 125 may be in contact with the first preliminary ferroelectric material film 120P, and the second sacrificial film 225 may be in contact with the second preliminary ferroelectric material film 220P. For example, the first sacrificial film 125 and the second sacrificial film 225 may be formed through the same fabricating process.

Each of the first sacrificial film 125 and the second sacrificial film 225 may include polysilicon. Each of the first sacrificial film 125 and the second sacrificial film 225 may be referred to as a polysilicon film.

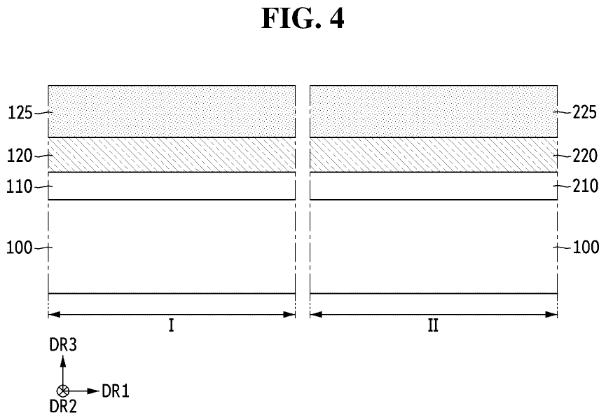

Referring to FIGS. 3 and 4, an annealing process is performed on the first stacked stack SS1 and the second stacked stack SS2. After the annealing process, a cooling process is performed on the first stacked stack SS1 and the second stacked stack SS2. The remanent polarization of the first preliminary ferroelectric material film 120P and the second preliminary ferroelectric material film 220P may be maximized by the annealing process and the cooling process, and the first ferroelectric material film 120 and the second ferroelectric material film 220 having an orthorhombic crystal structure may be formed.

The cooling rate in the cooling process may be, for example, 68 °C/sec or more. If the cooling rate is slow, it may be difficult to form crystals.

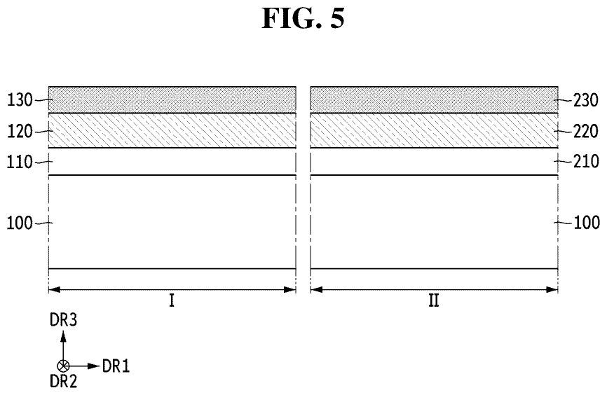

Referring to FIGS. 4 and 5, the first sacrificial film 125 and the second sacrificial film 225 are removed. For example, the first sacrificial film 125 and the second sacrificial film 225 may be removed through a stripping process. Accordingly, the first ferroelectric material film 120 and the second ferroelectric material film 220 may be exposed.

Next, the first gate insulating film 130 is formed on the exposed first ferroelectric material film 120, and the second gate insulating film 230 is formed on the exposed second ferroelectric material film 220. For example, the first gate insulating film 130 and the second gate insulating film 230 may be formed through the same fabricating process.

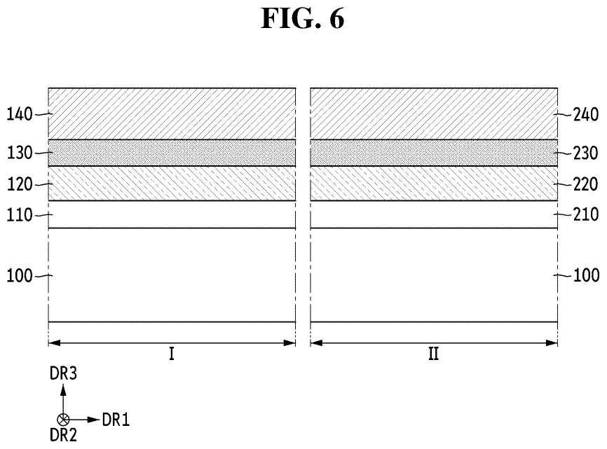

Referring to FIG. 6, the first gate electrode film 140 is formed on the first gate insulating film 130, and the second gate electrode film 240 is formed on the second gate insulating film 230. For example, the first gate electrode film 140 and the second gate electrode film 240 may be formed through the same fabricating process. The first gate electrode film 140 and the second gate electrode film 240 may include the same material and have the same thickness.

Next, referring to FIG. 1, the first gate capping film 150, the first gate spacer 160, and the first source/drain region 170 may be formed. The second gate capping film 250, the second gate spacer 260, and the second source/drain region 270 may be formed. Accordingly, the first transistor TR1 and the second transistor TR2 may be formed.

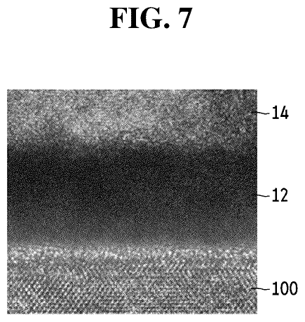

FIGS. 7 to 9 are diagrams for explaining a ferroelectric material film formed through a method for fabricating a semiconductor device according to some embodiments.

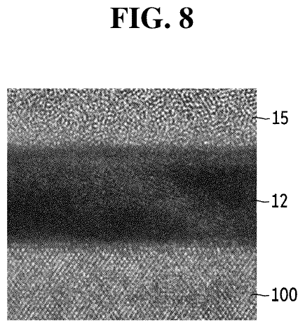

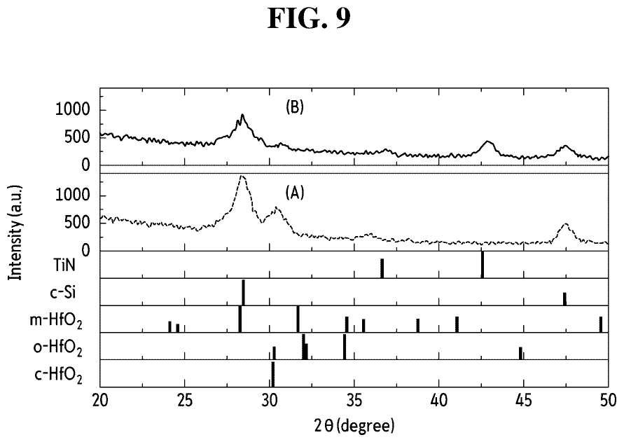

FIG. 7 is a TEM photograph of a case where the annealing process and the cooling process are performed after a hafnium oxide film 12 and a titanium nitride film 14 are formed on the first substrate 100. FIG. 8 is a TEM photograph of a case where the annealing process and the cooling process are performed after the hafnium oxide film 12 and the polysilicon film 15 are formed on the first substrate 100. (A) in FIG. 9 is a grazing incidence X-ray diffraction (hereinafter GIXRD) analysis pattern of the first substrate 100, the hafnium oxide film 12, and the titanium nitride film 14 after the annealing process and the cooling process of FIG. 7 are performed, and (B) in FIG. 9 is a GIXRD analysis pattern of the first substrate 100, the hafnium oxide film 12, and the polysilicon film 15 in which the annealing process and the cooling process of FIG. 8 are performed. In FIG. 9, a horizontal axis is a 20 value, a vertical axis is a peak intensity, c-Si is monocrystalline silicon, m-HfO₂ is a hafnium oxide film having a monoclinic structure (monoclinic HfO₂), o-HfO₂ is hafnium oxide film having a orthorhombic crystal structure (orthorhombic HfO₂), and c-HfO₂ is a hafnium oxide film (cubic HfO₂) having a cubic crystal structure.

Referring to FIGS. 7 and 8, unlike the case where the annealing process is performed with the hafnium oxide film 12 and the titanium nitride film 14 formed on the first substrate 100, when the annealing process is performed with the hafnium oxide film 12 and the polysilicon film 15 formed on the first substrate 100, the remanent polarization of the hafnium oxide film 12 is maximized, and the hafnium oxide film 12 may have an orthorhombic crystal structure.

Therefore, in the method for fabricating the semiconductor device according to some embodiments, since the annealing process is performed after forming the sacrificial films 125 and 225 including polysilicon on the preliminary ferroelectric material films 120P and 220P, the ferroelectric material films 120 and 220 having a larger remanent polarization and a orthorhombic crystal structure may be formed.

Referring to FIG. 9, in the case of (B), the peak intensity of the hafnium oxide film (o-HfO₂) having an orthorhombic crystal structure may be larger than in the case of (A).

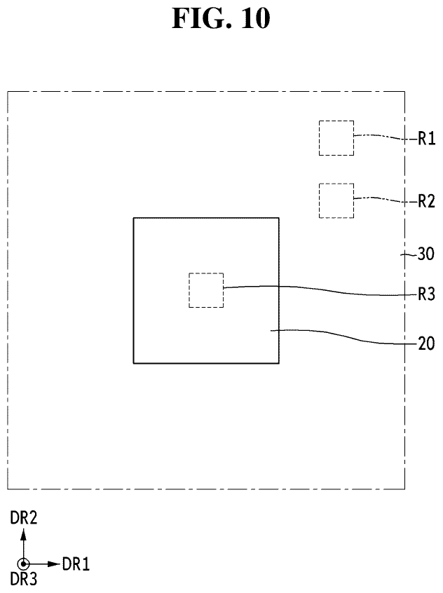

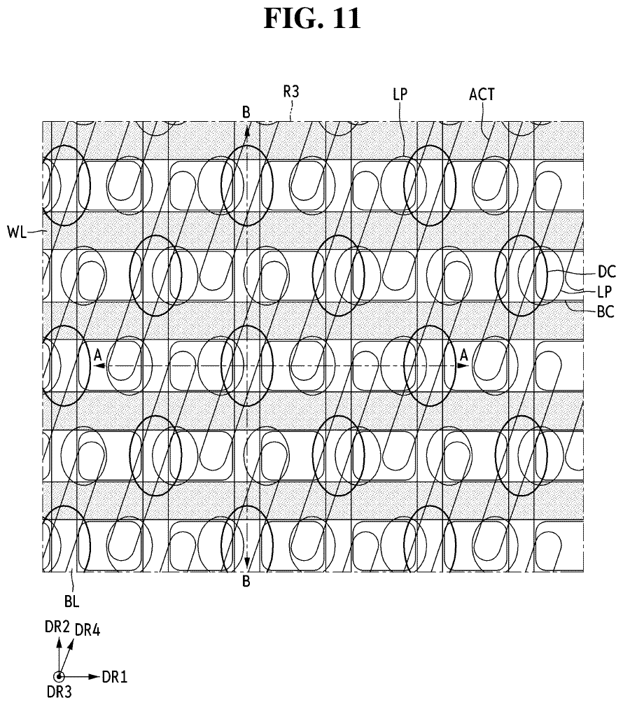

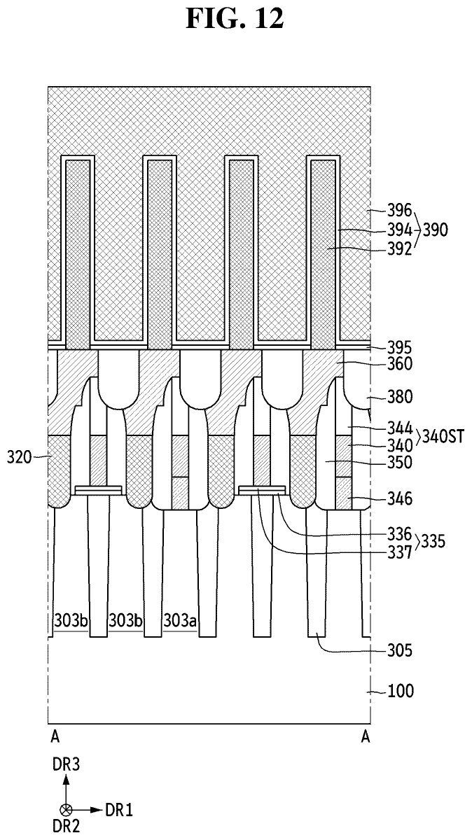

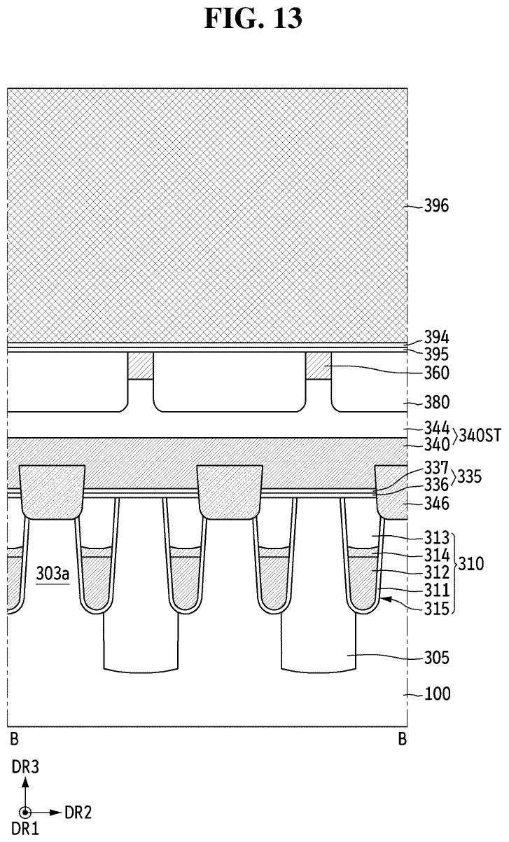

FIG. 10 is a schematic layout diagram of a semiconductor device according to some embodiments. FIG. 11 is a schematic layout diagram showing an enlarged view of a portion R3 of FIG. 10. FIG. 12 is a cross-sectional view taken along line A-A of FIG. 11. FIG. 13 is a cross-sectional view taken along line B-B of FIG. 11.

For reference, although a dynamic random access memory (DRAM) is shown as an example in the diagrams relating to the semiconductor device according to some embodiments, embodiments are not limited thereto. Also, FIG. 11 shows a layout diagram except a first capacitor 390.

Referring to FIG. 10, a semiconductor device according to some embodiments may include a memory cell region 20 and a peripheral region 30 defined around the memory cell region 20. In another embodiment, the substrate (100 of FIG. 1) may include the memory cell region 20 and the peripheral region 30. The memory cell region 20 may be a region in which a plurality of memory cells are disposed. In some embodiments, the plurality of memory cells included in the memory cell region 20 may be volatile memory cells (e.g., DRAM memory cells). The peripheral region 30 may be a region in which a circuit for operating the plurality of memory cells of the memory cell region 20 is disposed.

A cross-sectional view of a portion R1 of FIG. 10 cut in the first direction DR1 or the second direction DR2 may be a first cross-sectional view. A cross-sectional view of a portion R2 of FIG. 10 cut in the first direction DR1 or the second direction DR2 may be a second cross-sectional view. As an example, the first cross-sectional view may be a view shown in the first region I of FIG. 1. The second cross-sectional view may be a view shown in the second region II of FIG. 1. That is, the first peri-active region P_ACT1 may be located in the portion R1 of FIG. 10, and the second peri-active region P_ACT2 may be located in the portion R2 of FIG. 10, but is not limited thereto. Alternatively, the semiconductor device described using FIG. 1 may be disposed in the peripheral region 30 of FIG. 10. The first and second transistors TR1 and TR2 of FIG. 1 are electrically connected to a plurality of memory cells of the memory cell region 20.

Since the description of the portions R1 and R2 of FIG. 10 is the similar to that described using FIG. 1, the following description will focus on a portion R3 of FIG. 10.

Referring to FIG. 11, the semiconductor device according to some embodiments may include a plurality of cell active regions ACT. The cell active regions ACT may be defined by a cell element isolation film (305 of FIG. 12) formed in the first substrate (100 of FIG. 12). With a decrease in design rule of the semiconductor device, the cell active regions ACT may be disposed in the form of a bar of a diagonal line or an oblique line, as shown. For example, the cell active regions ACT may extend in a fourth direction DR4. The fourth direction DR4 is parallel to the upper side of the first substrate (100 of FIG. 12), and is a direction between the first direction DR1 and the second direction DR2.

A plurality of gate electrodes extending in the first direction DR1 across the cell active regions ACT may be disposed. The plurality of gate electrodes may extend parallel to each other. The plurality of gate electrodes may be, for example, a plurality of word lines WL. The word lines WL may be disposed at equal intervals. A width of the word lines WL or an interval between the word lines WL may be determined depending on the design rules.

Each cell active region ACT may be divided into three portions by two word lines WL extending in the first direction DR1. The cell active region ACT may include a storage connecting region 303b and a bit line connecting region 303a. The bit line connecting region 303a may be located at the central portion of the cell active region ACT, and the storage connecting region 303b may be located at the end of the cell active region ACT.

For example, the bit line connecting region 303a may be a region connected to the bit line BL, and the storage connecting region 303b may be a region connected to the first capacitor (390 of FIG. 12). In other words, the bit line connecting region 303a may correspond to a common drain region, and the storage connecting region 303b may correspond to a source region. Each word line WL, and the bit line connecting region 303a and the storage connecting region 303b adjacent thereto may form a transistor.

A plurality of bit lines BL extending in the second direction DR2 orthogonal to the word line WL may be disposed on the word line WL. The plurality of bit lines BL may extend parallel to each other. The bit lines BL may be disposed at equal intervals. The width of the bit lines BL or the interval between the bit lines BL may be determined depending on the design rule.

The semiconductor device according to some embodiments may include various contact arrangements formed on the cell active region ACT. The various contact arrangements may include, for example, a direct contact DC, a buried contact BC, a landing pad LP, and the like.

Here, the direct contact DC may mean a contact that electrically connects the cell active region ACT to the bit line BL. The buried contact BC may mean a contact that connects the cell active region ACT to a first lower electrode (392 of FIG. 12) of the first capacitor (390 of FIG. 12). A contact area between the buried contact BC and the cell active region ACT may be small due to the placement structure. Therefore, a conductive landing pad LP may be introduced to enlarge the contact area with the cell active region ACT and enlarge the contact area with the first lower electrode (392 of FIG. 12) of the first capacitor (390 of FIG. 12).

The landing pad LP may be disposed between the buried contact BC and the first lower electrode (392 of FIG. 12) of the first capacitor (390 of FIG. 12). By enlarging the contact area through the introduction of the landing pad LP, the contact resistance between the cell active region ACT and the first lower electrode (392 of FIG. 12) of the first capacitor (390 of FIG. 12) may decrease.

In the semiconductor device according to some embodiments, the direct contact DC may be disposed at the central portion of the cell active region ACT. The buried contact BC may be disposed at both end portions of the cell active region ACT. As the buried contact BC may be disposed at both end portions of the cell active region ACT, the landing pad LP may be disposed adjacent to both ends of the cell active region ACT to partially overlap the buried contact BC. In other words, the buried contact BC may be formed to overlap the cell active region ACT and the cell element isolation film (305 of FIG. 12) between the adjacent word lines WL and between the adjacent bit lines BL.

The word line WL may be formed as a structure buried inside the first substrate (100 of FIG. 12). The word line WL may be disposed across the cell active region ACT between the direct contact DC and the buried contact BC. As shown, two word lines WL may be disposed to cross one active region ACT. Since the cell active region ACT extends along the fourth direction DR4, the word line WL may have an angle less than 90 degrees with the cell active region ACT.

The direct contact DC and the buried contact BC may be disposed symmetrically. Therefore, the direct contact DC and the buried contact BC may be disposed on a straight line along the first direction DR1 and the second direction DR2. Meanwhile, unlike the direct contact DC and the buried contact BC, the landing pads LP may be disposed in a zigzag manner in the second direction DR2 in which the bit line BL extends. Also, the landing pads LP may be disposed to overlap the same side face portions of each bit line BL in the first direction DR1 in which the word line WL extends.

For example, each of the landing pads LP of the first line may overlap a left side of the corresponding bit line BL, and each of the landing pads LP of the second line may overlap a right side of the corresponding bit line BL.

Referring to FIGS. 11 to 13, the semiconductor device according to some embodiments may include a plurality of cell gate structures 310, a plurality of bit line structures 340ST, a plurality of storage contacts 320, a plurality of bit line contacts 346, and a first capacitor 390.

The cell element isolation film 305 may be formed in the first substrate 100. The cell element isolation film 305 may have a shallow trench isolation (STI) structure having excellent element isolation characteristics. The cell element isolation film 305 may define a cell active region ACT inside the memory cell region.

The cell active region ACT defined by the cell element isolation film 305 may have a long island shape including a short axis and a long axis, as shown in FIG. 11. The cell active region ACT may have an oblique line shape to have an angle of less than 90 degrees with respect to the word line WL formed inside the cell element isolation film 305. Further, the cell active region ACT may have an oblique line shape to have an angle of less than 90 degrees with respect to the bit line BL formed on the cell element isolation film 305.

The cell gate structure 310 may be formed inside the first substrate 100 and the cell element isolation film 305. The cell gate structure 310 may be formed across the cell element isolation film 305, and the cell active region ACT defined by the cell element isolation film 305.

The cell gate structure 310 is formed inside the first substrate 100 and the cell element isolation film 305. The cell gate structure 310 may include a cell gate trench 315, a cell gate insulating film 311, a cell gate electrode 312, a cell gate capping pattern 313, and a cell gate capping conductive film 314. Here, the cell gate electrode 312 may correspond to the word line WL of FIG. 11.

The cell gate insulating film 311 may extend along the side walls and bottom face of the cell gate trench 315. The cell gate insulating film 311 may extend along the profile of at least a part of the cell gate trench 315. The cell gate insulating film 311 may include at least one of silicon oxide, silicon nitride, silicon oxynitride or a high dielectric constant material having a higher dielectric constant than silicon oxide.

The cell gate electrode 312 may be disposed on the cell gate insulating film 311. The cell gate electrode 312 may fill a part of the cell gate trench 315. The cell gate electrode 312 may include at least one of a metal, a conductive metal nitride, a conductive metal carbonitride, a conductive metal carbide, a metal silicide, a doped semiconductor material, a conductive metal oxynitride, and a conductive metal oxide.

The cell gate capping pattern 313 may be disposed on the cell gate electrode 312. The cell gate capping pattern 313 may fill the remaining part of the cell gate trench 315 in which the cell gate electrode 312 is formed. The cell gate capping pattern 313 includes an insulating material.

Although not shown, an impurity-doped region may be formed on at least one side of the cell gate structure 310. The impurity-doped region may be a source/drain region of the transistor.

The bit line structure 340ST may include a cell conductive line 340 and a cell line capping film 344. The cell conductive line 340 may be disposed on the first substrate 100 and the cell element isolation film 305 on which the cell gate structure 310 is disposed. The cell conductive line 340 may intersect the cell element isolation film 305, and the cell active region ACT defined by the cell element isolation film 305. The cell conductive line 340 may be formed to intersect the cell gate structure 310. Here, the cell conductive line 340 may correspond to the bit line BL of FIG. 11.

The cell conductive line 340 may include a conductive material. Although the cell conductive line 340 is shown as being a single film, this is only for convenience of explanation, and embodiments are not limited thereto. That is, unlike that shown, the cell conductive line 340 may include a plurality of conductive films with conductive materials stacked together.

The cell line capping film 344 may be disposed on the cell conductive line 340. The cell line capping film 344 may extend in the second direction DR2 along the upper side of the cell conductive line 340. The cell line capping film 344 may include an insulating material.

A bit line contact 346 may be formed between the cell conductive line 340 and the first substrate 100. The cell conductive line 340 may be disposed on the bit line contact 346. The bit line contact 346 may be formed between the bit line connecting region 303a of the cell active region ACT and the cell conductive line 340. The bit line contact 346 may be connected to the bit line connecting region 303a.

The bit line contact 346 may electrically connect the cell conductive line 340 and the first substrate 100. Here, the bit line contact 346 may correspond to the direct contact DC of FIG. 11. The bit line contact 346 may include, for example, at least one of an impurity-doped semiconductor material, a conductive metal silicide, a conductive metal nitride, a conductive metal oxide, a metal, and a metal alloy.

A cell insulating film 335 may be disposed on the first substrate 100 and the cell element isolation film 305. The cell insulating film 335 may be formed on the first substrate 100 and the cell element isolation film 305 on which the bit line contact 346 is not formed. The cell insulating film 335 may be formed between the first substrate 100 and the cell conductive line 340, and between the cell element isolation film 305 and the cell conductive line 340. The cell insulating film 335 may be a single film, but as shown, the cell insulating film 335 may be a multi-layer film including the first cell insulating film 336 and the second cell insulating film 337. For example, the first cell insulating film 336 may include a silicon oxide film, and the second cell insulating film 337 may include, but is not limited to, a silicon nitride film.

A bit line spacer 350 may be disposed on the side walls of the cell conductive line 340 and the cell line capping film 344. Although the bit line spacer 350 is shown as being a single film, this is only for convenience of explanation, and embodiments are not limited thereto. In other words, unlike the shown example, it goes without saying that the bit line spacer 350 may have a multi-layer structure. The bit line spacer 350 may include, for example, but is not limited to, a silicon oxide film, a silicon nitride film, a silicon oxynitride film (SiON), a silicon oxycarbonitride film (SiOCN), air, and combinations thereof.

A storage contact 320 may be disposed between the cell conductive lines 340 adjacent in the first direction DR1. The storage contact 320 may overlap the first substrate 100 and the cell element isolation film 305 between the adjacent cell conductive lines 340. The storage contact 320 may be connected to the storage connecting region 303b of the cell active region ACT. Here, the storage contact 320 may correspond to the buried contact BC of FIG. 11. The storage contact 320 may include, for example, at least one of an impurity-doped semiconductor material, a conductive metal silicide, a conductive metal nitride, a conductive metal carbide, a conductive metal carbonitride, a conductive metal oxide, a metal, and a metal alloy.

A storage pad 360 may be disposed on the storage contact 320. The storage pad 360 may be electrically connected to the storage contact 320. Here, the storage pad 360 may correspond to the landing pad LP of FIG. 11. The storage pad 360 may include, for example, at least one of an impurity-doped semiconductor material, a conductive metal silicide, a conductive metal nitride, a conductive metal carbide, a conductive metal oxide, a metal, and a metal alloy.

A pad isolation insulating film 380 may be formed on the storage pad 360 and the bit line structure 340ST. For example, the pad isolation insulating film 380 may be disposed on the cell line capping film 344. The pad isolation insulating film 380 may define the storage pad 360 that forms a plurality of isolation regions. Also, the pad isolation insulating film 380 may be patterned to expose at least a part of an upper side of the storage pad 360. The pad isolation insulating film 380 includes an insulating material.

An etching stop film 395 may be disposed on the storage pad 360 and the pad isolation insulating film 380. The etching stop film 395 may include at least one of a silicon nitride film, a silicon carbonitride film, a silicon boron nitride film (SiBN), a silicon oxynitride film, and a silicon oxycarbide film.

The first capacitor 390 may be disposed on the storage pad 360. The first capacitor 390 may be electrically connected to the storage pad 360. A part of the first capacitor 390 may be disposed inside the etching stop film 395. The first capacitor 390 includes a first lower electrode 392, a first capacitor dielectric film 394, and a first upper electrode 396.

The first lower electrode 392 may be connected to the storage pad 360. For example, the first lower electrode 392 may be in contact with a part of the upper side of the storage pad 360 exposed by the etching stop film 395. The first lower electrode 392 is shown to have a pillar shape extending in the third direction DR3, but is not limited thereto. The first lower electrode 392 may, of course, has a cylindrical shape.

The first capacitor dielectric film 394 is disposed on the first lower electrode 392. The first capacitor dielectric film 394 may extend along the profile of the first lower electrode 392. The first upper electrode 396 is disposed on the first capacitor dielectric film 394. The first upper electrode 396 is only shown to fill a region between adjacent first lower electrodes 392, but this is merely an example. As another example, the first upper electrode 396 may extend along the profile of the first capacitor dielectric film 394.

Each of the first lower electrode 392 and the first upper electrode 396 may include, but is not limited to, a doped semiconductor material, a conductive metal nitride (e.g., titanium nitride, tantalum nitride, niobium nitride, or tungsten nitride, etc.), a metal (e.g., ruthenium, iridium, titanium, or tantalum, etc.), and a conductive metal oxide (e.g., iridium oxide, niobium oxide, etc.).

The first capacitor dielectric film 394 may include, for example, but is not limited to, one of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

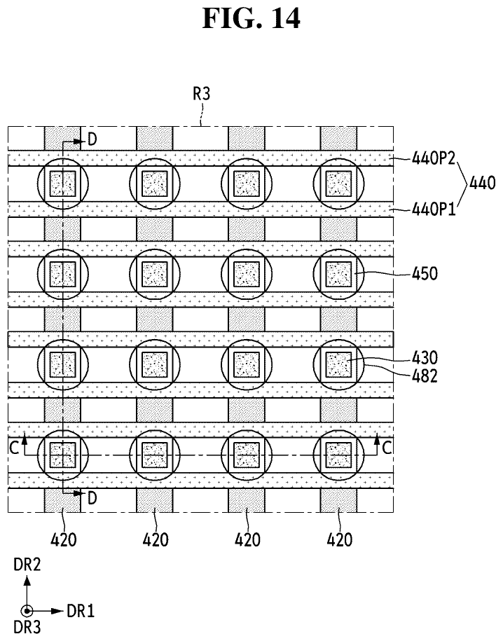

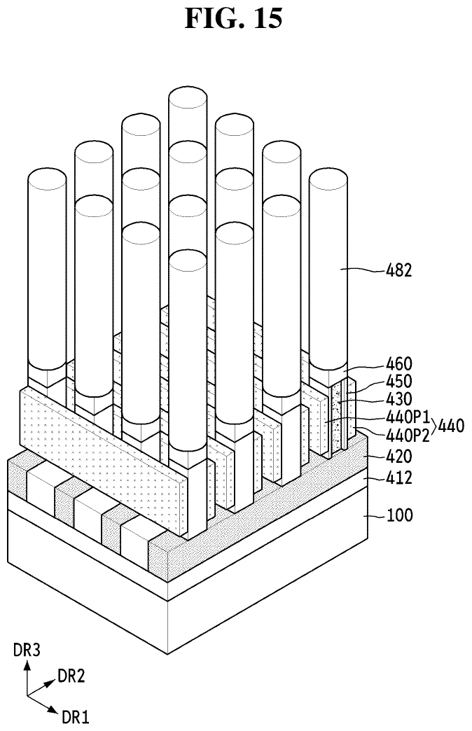

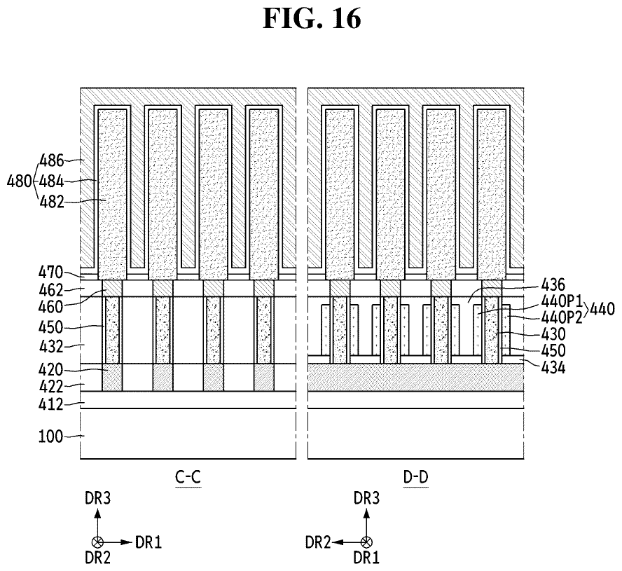

FIG. 14 is a layout diagram for explaining a semiconductor device according to some embodiments. FIG. 15 is a perspective view for explaining the semiconductor device according to some embodiments. FIG. 16 is a cross-sectional view taken along C-C and D-D of FIG. 14. For reference, FIG. 14 may be an enlarged view of a portion R3 of FIG. 10.

Referring to FIGS. 14 to 16, the semiconductor device according to some embodiments may include a first substrate 100, a plurality of first conductive lines 420, a channel layer 430, a fourth gate electrode 440, a fourth gate insulating film 450, and a second capacitor 480. The semiconductor device according to some embodiments may include memory cells including a vertical channel transistor (VCT). The vertical channel transistor may refer to a structure in which a channel length of the channel layer 430 extends along a vertical direction (third direction DR3) from the first substrate 100.

A lower insulating layer 412 may be disposed on the first substrate 100. A plurality of first conductive lines 420 may be spaced apart from each other in the first direction DR1 and extend in the second direction DR2 on the lower insulating layer 412. A plurality of first insulating patterns 422 may be disposed on the lower insulating layer 412 to fill spaces between the plurality of first conductive lines 420. The plurality of first insulating patterns 422 may extend in the second direction DR2. Upper sides of the plurality of first insulating patterns 422 may be disposed at the same level as upper sides of the plurality of first conductive lines 420. The plurality of first conductive lines 420 may function as bit lines.

The plurality of first conductive lines 420 may include a doped semiconductor material, metal, conductive metal nitride, conductive metal silicide, conductive metal oxide, or combinations thereof. For example, the plurality of first conductive lines 420 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. The plurality of first conductive lines 420 may include a single layer or multi-layers of the above-mentioned materials. In some embodiments, the plurality of first conductive lines 420 may include graphene, carbon nanotube or a combination thereof.

The channel layers 430 may be arranged in the form of a matrix in which they are disposed apart from each other in the first direction DR1 and the second direction DR2 on the plurality of first conductive lines 420. The channel layer 430 may have a first width along the first direction DR1 and a first height along the third direction DR3, and the first height may be greater than the first width. For example, the first height may be, but is not limited to, about 2 to 10 times the first width. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

In the exemplary examples, the channel layer 430 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multi-layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 may have optimum channel performance when having the bandgap energy of about 2.0 eV to 4.0 eV. For example, the channel layer 430 may be, but is not limited to, polycrystalline or amorphous. In the exemplary examples, the channel layer 430 may include graphene, carbon nanotube or a combination thereof. As yet another example, the channel layer 430 may include graphene, carbon nanotube or a combination thereof.

A fourth gate electrode 440 may extend in the first direction DR1 on both side walls of the channel layer 430. The fourth gate electrode 440 may include a first sub-gate electrode 440P1 that faces a first side wall of the channel layer 430, and a second sub-gate electrode 440P2 that faces a second side wall opposite to the first side wall of the channel layer 430. As the single channel layer 430 is disposed between the first sub-gate electrode 440P1 and the second sub-gate electrode 440P2, the semiconductor device may have a dual gate transistor structure. However, the technical idea of the present disclosure is not limited thereto, the second sub-gate electrode 440P2 may be omitted, and only the first sub-gate electrode 440P1 that faces the first side wall of the channel layer 430 may be formed to realize a single gate transistor structure. The materials included in the fourth gate electrode 440 may be the same as description of the cell gate electrode 312.

A fourth gate insulating film 450 surrounds side walls of the channel layer 430 and may be interposed between the channel layer 430 and the fourth gate electrode 440. For example, as shown in FIG. 14, the entire side wall of the channel layer 430 may be surrounded by the fourth gate insulating film 450, and a part of the side wall of the fourth gate electrode 440 may be in contact with the fourth gate insulating film 450. In embodiments, the fourth gate insulating film 450 extends in an extending direction (i.e., the first direction DR1) of the fourth gate electrode 440, and only the two side walls that face the fourth gate electrode 440 among the side walls of the channel layer 430 may be in contact with the fourth gate insulating film 450. In the exemplary embodiments, the fourth gate insulating film 450 may be made up of a silicon oxide film, a silicon oxynitride film, a high dielectric constant material having a higher dielectric constant than the silicon oxide film, or a combination thereof.

A plurality of second insulating patterns 432 may extend along the second direction DR2 on the plurality of first insulating patterns 422. The channel layer 430 may be disposed between two adjacent second insulating patterns 432 among the plurality of second insulating patterns 432. Further, a first buried layer 434 and a second buried layer 436 may be disposed in a space between two adjacent channel layers 430, between two adjacent second insulating patterns 432. The first buried layer 434 may be disposed at the bottom portion of the space between two adjacent channel layers 430. The second buried layer 436 may be formed to fill the remainder of the space between two adjacent channel layers 430 on the first buried layer 434. The upper side of the second buried layer 436 may be disposed at the same level as the upper side of the channel layer 430, and the second buried layer 436 may cover the upper side of the fourth gate electrode 440. In contrast, the plurality of second insulating patterns 432 may be formed of a continuous material layer with the plurality of first insulating patterns 422, or the second buried layer 436 may be formed of a continuous material layer with the first buried layer 434.

Capacitor contacts 460 may be disposed on the channel layer 430. The capacitor contacts 460 are disposed to vertically overlap the channel layer 430, and may be arranged in the form of a matrix in which they are spaced apart from each other in the first direction DR1 and the second direction DR2. The capacitor contacts 460 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. An upper insulating layer 462 may surround the side walls of the capacitor contacts 460 on the plurality of second insulating patterns 432 and the second buried layer 436.

An etching stop film 470 may be disposed on the upper insulating layer 462, and a second capacitor 480 may be disposed on the etching stop film 470. The second capacitor 480 may include a second lower electrode 482, a second capacitor dielectric film 484, and a second upper electrode 486. The second lower electrode 482 penetrates the etching stop film 470 and may be electrically connected to the upper side of the capacitor contact 460. The second lower electrode 482 may be formed, but is not limited to, in a pillar type extending in the third direction DR3. In the exemplary embodiments, the second lower electrodes 482 are disposed to vertically overlap the capacitor contacts 460, and may be arranged in the form of a matrix in which they are spaced apart from each other in the first direction DR1 and the second direction DR2. In contrast, a landing pad (not shown) is further disposed between the capacitor contact 460 and the second lower electrode 482, and the second lower electrode 482 may be arranged in a hexagonal shape.

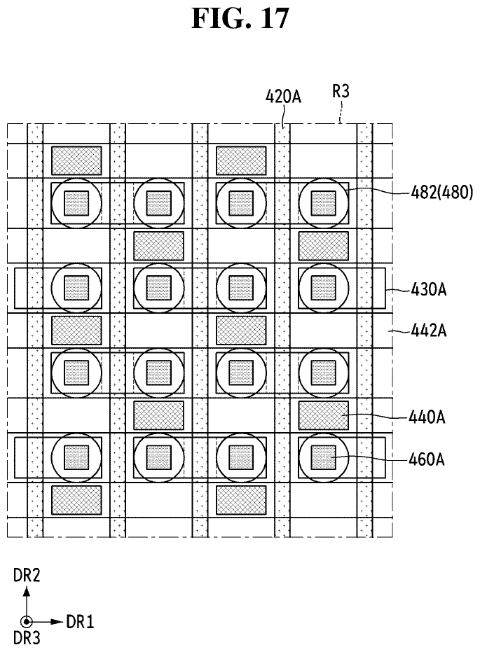

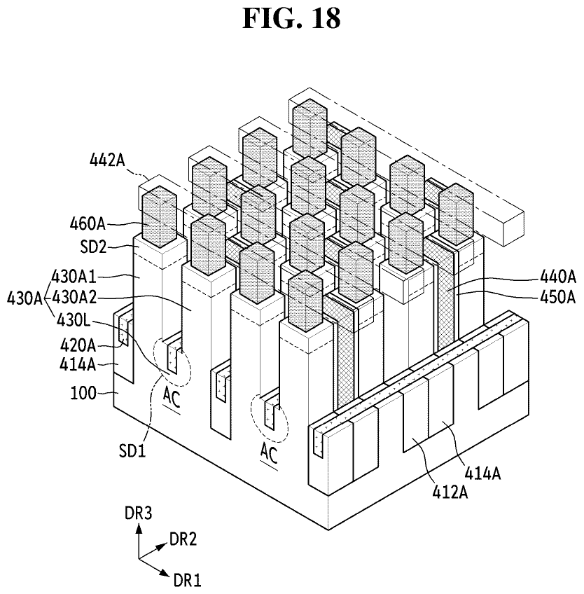

FIG. 17 is a layout diagram for explaining a semiconductor device according to some embodiments. FIG. 18 is a perspective view for explaining the semiconductor device according to some embodiments. For reference, FIG. 17 may be an enlarged view of a portion R3 of FIG. 10.

Referring to FIGS. 17 and 18, the semiconductor device according to some embodiments may include a substrate 100, a plurality of first conductive lines 420A, a channel structure 430A, a contact gate electrode 440A, a plurality of second conductive lines 442A, and a capacitor 480. The semiconductor device according to some embodiments may include memory cells including a vertical channel transistor VCT.

A plurality of second cell active regions AC may be defined by the first element isolation pattern 412A and the second element isolation pattern 414A on the substrate 100. The channel structure 430A may be disposed in each second cell active region AC. The channel structure 430A may include a first active pillar 430A1 and a second active pillar 430A2 that each extend in the vertical direction (third direction DR3), and a connecting portion 430L connected to a bottom portion of the first active pillar 430A1 and a bottom portion of the second active pillar 430A2. A third source/drain region SD1 may be disposed inside the connecting portion 430L. A fourth source/drain region SD2 may be disposed above the first and second active pillars 430A1 and 430A2. Each of the first active pillar 430A1 and the second active pillar 430A2 may form an independent unit memory cell.

The plurality of first conductive lines 420A may extend in a direction intersecting each of the plurality of second cell active regions AC, and may extend, for example, in the second direction DR2. One first conductive line 420A among the plurality of first conductive lines 420A may be disposed on the connecting portion 430L between the first active pillar 430A1 and the second active pillar 430A2. One first conductive line 420A may be disposed on the third source/drain region SD1. The other first conductive line 420A adjacent to the one first conductive line 420A may be disposed between the two channel structures 430A. One first conductive line 420A among the plurality of first conductive lines 420A may function as a common bit line included in the two unit memory cells constituted by the first active pillar 430A1 and the second active pillar 430A2 disposed on both sides of the one first conductive line 420A.

One contact gate electrode 440A may be disposed between the two channel structures 430A adjacent to each other in the second direction DR2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 disposed on both side walls thereof. A fourth gate insulating film 450A may be disposed between the contact gate electrode 440A and the first active pillar 430A1, and between the contact gate electrode 440A and the second active pillar 430A2. The plurality of second conductive lines 442A may extend in the first direction DR1 on the upper side of the contact gate electrode 440A. The plurality of second conductive lines 442A may function as word lines of the semiconductor device.

A capacitor contact 460A may be disposed on the channel structure 430A. The capacitor contact 460A may be disposed on the second source/drain region SD2, and the second capacitor 480 may be disposed on the capacitor contact 460A.

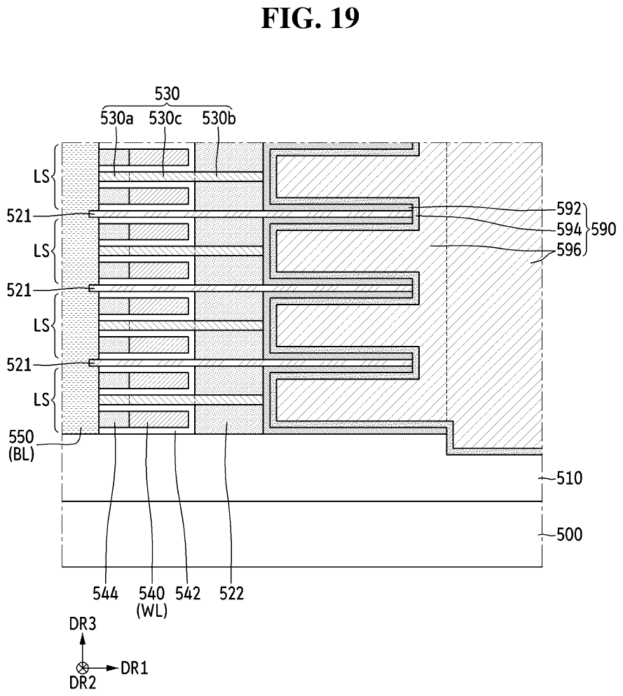

FIG. 19 is diagram for explaining a semiconductor device according to some embodiments. For reference, FIG. 19 may be a cross-sectional view of the semiconductor device.

Referring to FIG. 19, the semiconductor device according to some embodiments may include a second substrate 500, a lower structure 510 on the second substrate 500, a plurality of structures LS and a plurality of first insulating layers 521 alternately stacked on the second substrate 500, and a second conductive pattern 550.

The second substrate 500 may be a silicon substrate or a silicon-on-insulator (SOI). In contrast, the second substrate 500 may include, but is not limited to, silicon germanium, silicon germanium on insulator (SGOI), indium antimonide, lead telluride, indium arsenide, indium phosphide, gallium arsenide or gallium antimonide.

Each of the plurality of structures LS may include an active layer 530 extending in a first direction DR1, a first conductive pattern 540 intersecting the active layer 530 and extending in the second direction DR2 perpendicular to the first direction DR1, a gate insulating pattern 542 between the active layer 530 and the first conductive pattern 540, a gate capping film 544 between the first conductive pattern 540 and the second conductive pattern 550, a third lower electrode 592 of a third capacitor 590, and a second insulating layer 522 between the first conductive pattern 540 and the third lower electrode 592.

The third capacitor 590 may include a third lower electrode 592, a third capacitor dielectric film 594, and a third upper electrode 596. The third capacitor dielectric film 594 is disposed between the third lower electrode 592 and the third upper electrode 596.

The lower structure 510 may be disposed on the second substrate 500. A plurality of structures LS and a plurality of first insulating layers 521 may be stacked on the lower structure 510. The lower structure 510 may include an element region on the second substrate 500, and an insulating region that covers the element region. The insulating region may be formed of an insulating film including an insulating material, for example, at least one of silicon oxide, silicon nitride, silicon oxynitride, and silicon oxycarbide.

The plurality of structures LS and the plurality of first insulating layers 521 may form a mold structure on the second substrate 500. The plurality of structures LS may be disposed between the plurality of first insulating layers 521, and may be spaced apart from each other in the third direction DR3 by the plurality of first insulating layers 521. The first insulating layer 521 may extend along the first direction DR1, and an end portion thereof may extend into the second conductive pattern 550. The second insulating layer 522 may be disposed between the first insulating layer 521 and the active layer 530, and between the first conductive pattern 540 and the third capacitor 590. Each of the first insulating layer 521 and the second insulating layer 522 may include insulating materials, for example, at least one of silicon oxide, silicon nitride, silicon oxynitride, and silicon oxycarbide. The first insulating layer 521 may extend horizontally to be longer than the second insulating layer 522. The thickness of the second insulating layer 522 may be thicker than the thickness of the first insulating layer 521.

The active layer 530 may be disposed on the second substrate 500 and extend horizontally in the first direction DR1. A plurality of active layers 530 may be stacked to be spaced apart from each other in the third direction DR3, and may be arranged in the second direction DR2. The plurality of active layers 530 arranged in the third direction DR3 may be disposed between the plurality of first insulating layers 521. The active layers 530 may have a line shape, a bar shape or a columnar shape that crosses the first conductive pattern 540 and extends in the first direction DR1. The active layers 530 may include a semiconductor material, for example, silicon, germanium or silicon-germanium.

The active layer 530 may include a first impurity region 530a, a second impurity region 530b, and a channel region 530c. The first impurity region 530a may be electrically connected to the second conductive pattern 550. The second impurity region 530b may be electrically connected to the third lower electrode 592 of the third capacitor 590. Although the length of the second impurity region 530b in the first direction DR1 may be longer than the length of the first impurity region 530a in the first direction DR1, embodiments are not limited thereto. The channel region 530c may be disposed between the first impurity region 530a and the second impurity region 530b. The channel region 530c may overlap the first conductive pattern 540. The first impurity region 530a and the second impurity region 530b may be spaced apart from each other in the horizontal direction and disposed at the same level, and the channel region 530c may be a horizontal channel region.

The first impurity region 530a and the second impurity region 530b may be formed by performing doping of impurities or ion implantation process on the active layer 530. The first impurity region 530a and the second impurity region 530b may include n-type or p-type impurities.

A part of the first impurity region 530a may correspond to a source region of the transistor, a part of the second impurity region 530b may correspond to a drain region of the transistor, and the channel region 530c may correspond to a channel of the transistor. A part of the first impurity region 530a may provide a first contact region for directly connecting the source region of the transistor to the second conductive pattern 550, i.e., the bit line BL, and a part of the second impurity region 530b may provide a second contact region for directly connecting the drain region of the transistor to the third capacitor 590.

In another example, the active layers 530 may include an oxide semiconductor, for example, hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In another example, the active layer 530 may include a two-dimensional material (2D material) in which atoms may form a predetermined crystal structure and form a channel of a transistor. The two-dimensional material layer included in the active layer 530 may include at least one of a transition metal dichalcogenide material layer (TMD material layer), a black phosphorous material layer, and a hexagonal boron-nitride material layer (hBN material layer). For example, the two-dimensional material layer included in the active layer 530 may include at least one of BiOSe, Crl, WSe₂, MoS₂, TaS, WS, SnSe, ReS, β-SnTe, MnO, AsS, P (black), InSe, h-BN, GaSe, GaN, SrTiO, MXene, and Janus 2D materials.

The first conductive pattern 540 may be disposed on the second substrate 500 and extend horizontally in the second direction DR2. A plurality of first conductive patterns 540 may be stacked to be spaced apart from each other in the third direction DR3 and arranged in the first direction DR1. The first conductive pattern 540 may be disposed between the channel region 530c of the active layer 530 and the first insulating layer 521. The first conductive pattern 540 may be disposed on the upper and lower sides of the active layer 530. The first conductive pattern 540 may have a line shape, a rod shape, or a columnar shape that intersects the second conductive pattern 550 and extends in the second direction DR2. Although not shown, each of the plurality of first conductive patterns 540 stacked in the third direction DR3 inside one memory cell may extend at different lengths in the second direction DR2 to provide contact regions in which the upper sides are exposed.

The first conductive pattern 540 may include a conductive material, which may include at least one of a doped semiconductor material, a conductive metal nitride, a metal, or a metal silicide. The first conductive pattern 540 may be a word line WL, and may be referred to as a “gate electrode”.

The gate insulating pattern 542 may be disposed between the first conductive pattern 540 and the active layer 530. The gate insulating pattern 542 may be formed between adjacent first insulating layers 521 to have a substantially conformal thickness in the internal space of the gap region formed by etching the second insulating layer 522 from the side face. The gate insulating pattern 542 may include silicon oxide, silicon nitride or a high dielectric constant (high-k) material.

The gate capping film 544 may be disposed to fill a region in which the first conductive pattern 540 is partially removed from the side face. For example, the side face of the gate capping film 544 may be in contact with the side face of the first conductive pattern 540, and the upper and lower sides may be covered by the gate insulating pattern 542. The gate capping film 544 may electrically insulate the first conductive pattern 540 from the second conductive pattern 550.

The second conductive pattern 550 may extend perpendicularly in the third direction DR3 on the second substrate 500. A plurality of second conductive patterns 550 may be arranged in the second direction DR2. The second conductive pattern 550 may be disposed adjacent to the first impurity region 530a and the first end side of the active layer 530. A plurality of active layers 530 stacked in the third direction DR3 may be electrically connected to one second conductive pattern 550. The second conductive pattern 550 may have a line, bar, or columnar shape extending in the third direction DR3. Although not shown, the semiconductor device may further include an upper wiring which is disposed on the second conductive pattern 550, is connected to the second conductive pattern 550, and extends in the first direction DR1. The second conductive pattern 550 may include at least one of a doped semiconductor material, a conductive metal nitride, a metal or a metal silicide.

The third capacitor 590 may be disposed to be adjacent to the second impurity region 530b and the second end side of the active layer 530. The third capacitor 590 may be electrically connected to the active layer 530. The third lower electrode 592 may have a cylindrical shape, but is not limited thereto, and may have a pillar shape in the embodiments.

The third lower electrode 592 may be formed to have a substantially conformal thickness in an internal space of a gap region formed by etching the second insulating layer 522 from the side face. The third lower electrode 592 may be in a state in which the nodes are separated for each of the structures LS by removing the portion on the side face of the first insulating layer 521 after depositing a conductive material.

In some embodiments, FIG. 19 may be a cross-sectional view of a portion R3 of FIG. 10 cut in the first direction DR1. The first transistor TR1 and the second transistor TR2 of FIG. 1 may be electrically connected to the memory cells of FIG. 19.

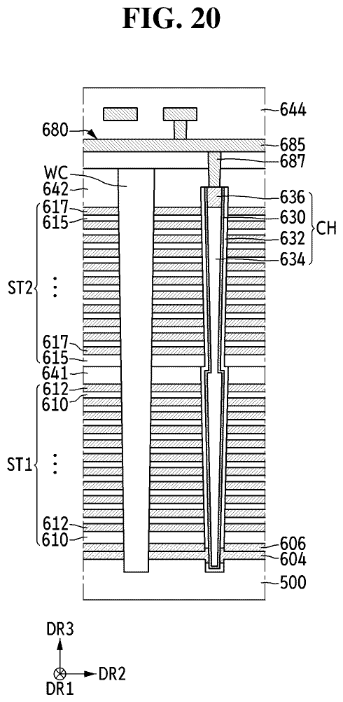

FIG. 20 is a diagram for explaining a semiconductor device according to some embodiments. For reference, FIG. 20 may be a cross-sectional view of the semiconductor device.

Referring to FIG. 20, the semiconductor device according to some embodiments may include a plurality of non-volatile memory cells. For example, the semiconductor device may include a second substrate 500, stacked structures ST1 and ST2, interlayer insulating films 641 and 642, a channel structure CH, a cutting pattern WC, and a wiring structure 680.

The stacked structures ST1 and ST2 may be disposed on the second substrate 500. The stacked structures ST1 and ST2 may include a plurality of mold insulating films 610 and 615 and a plurality of gate electrodes 612 and 617 that are stacked on the second substrate 500. Each of the mold insulating films 610 and 615 and each of the gate electrodes 612 and 617 may have a layered structure extending along a horizontal plane (e.g., a plane including the first direction DR1 and the second direction DR2). The gate electrodes 612 and 617 may be sequentially stacked while being spaced apart from each other by the mold insulating films 610 and 615. Although the stacked structures ST1 and ST2 are shown as including a first stacked structure ST1 and a second stacked structure ST2 that are stacked in sequence on the second substrate 500, this is only for convenience of explanation and embodiments are not limited thereto, and the stacked structures ST1 and ST2 include three or more stacked structures.

The first stacked structure ST1 may include first mold insulating films 610 and first gate electrodes 612 which are alternately stacked on the second substrate 500. In some embodiments, the first gate electrodes 612 may include at least one ground selection line and a plurality of first word lines which are stacked in sequence on the second substrate 500. The second stacked structure ST2 may include second mold insulating films 615 and second gate electrodes 617 which are alternately stacked on the first stacked structure ST1. In some embodiments, the second gate electrodes 617 may include a plurality of second word lines and at least one string selection line which are stacked in sequence on the first stacked structure ST1. The numbers, shapes and the like of the first mold insulating films 610, the first gate electrodes 612, the second mold insulating films 615, and the second gate electrode 617 are merely an example, and are not limited to those shown in the drawings.

Each of the first and second gate electrodes 612 and 617 may include a conductive material or polysilicon. The first and second gate electrodes 612 and 617 may include an insulating material.

The interlayer insulating films 641 and 642 may be formed on the second substrate 500 to cover the stacked structures ST1 and ST2. The first interlayer insulating film 641 may be formed on the first stacked structure ST1 to cover the first stacked structure ST1, and the second interlayer insulating film 642 may be formed on the second stacked structure ST2 to cover the second stacked structure ST2. The interlayer insulating films 641 and 642 may include, but are not limited to, at least one of silicon oxide, silicon oxynitride, and a low dielectric constant material having a lower dielectric constant than silicon oxide.

The channel structure CH may extend in the vertical direction (e.g., the third direction DR3) to intersect the plurality of gate electrodes 612 and 617. For example, the channel structure CH may extend in the third direction DR3 and penetrate the stacked structures ST1 and ST2. The channel structure CH may be a pillar-shaped (e.g., cylindrical) structure extending in the third direction DR3. In some embodiments, the plurality of channel structures CH may be arranged in a zigzag form. For example, the channel structures CH may be arranged alternately with each other in the first direction DR1 and the second direction DR2.

In some embodiments, each channel structure CH may have a step between the first stacked structure ST1 and the second stacked structure ST2. For example, the side faces of each channel structure CH may have a bending portion at a boundary between the first interlayer insulating film 641 and the second stacked structure ST2.

The channel structure CH may include a channel pattern 630 and a data storage pattern 632.

The channel pattern 630 may extend in the third direction DR3 and intersect the plurality of gate electrodes 612 and 617. The channel pattern 630 may include, but is not limited to, a semiconductor material, such as, for example, monocrystalline silicon, polycrystalline silicon, an organic semiconductor matter or a carbon nanostructure.

The data storage pattern 632 may be interposed between the channel pattern 630 and the plurality of gate electrodes 612 and 617. For example, the data storage pattern 632 may conformally extend along the profile of the outer side face of the channel pattern 630.

In some embodiments, the channel structure CH may further include a filling insulating film 634. The filling insulating film 634 may be formed to fill the inside of the cup-shaped channel pattern 630. The filling insulating film 634 may include, but is not limited to, an insulating material, for example, silicon oxide.

In some embodiments, the channel structure CH may further include a channel pad 636. The channel pad 636 may be formed to connect to one end (e.g., an upper end) of the channel pattern 630. The channel pad 636 may include, but is not limited to, a conductive material, for example, impurity-doped polysilicon, metal or metal silicide.

In some embodiments, a source layer 604 and a source support layer 606 may be formed between the second substrate 500 and the stacked structures ST1 and ST2.

The source layer 604 may extend along the upper side of the second substrate 500. The source layer 604 may be electrically connected to the channel pattern 630. For example, the source layer 604 may penetrate the data storage pattern 632 and come into contact with a side face of the channel pattern 630. The source layer 604 may include, but is not limited to, a conductive material, for example, polysilicon doped with impurities, metal or the like.

The source support layer 606 may be formed on the second substrate 500 and the source layer 604. For example, the source support layer 606 may extend along the upper side of the source layer 604. The source support layer 606 may include, but is not limited to, a polysilicon film.

The stacked structures ST1 and ST2 may be divided by a cutting pattern WC to form memory cell blocks. The cutting pattern WC may include an insulating material.

The wiring structure 680 may be formed on the second interlayer insulating film 642. The wiring structure 680 may be electrically connected to the source layer 604, the gate electrodes 612 and 617, and/or the channel structure CH. For example, an inter-wiring insulating film 644 may be formed on the second interlayer insulating film 642. The wiring structure 680 may be formed inside the inter-wiring insulating film 644 and connected to the source layer 604, the gate electrodes 612 and 617, and/or the channel structure CH. The number of layers and the arrangement of the wiring structure 680 are merely exemplary and are not limited to those shown in the drawings. The wiring structure 680 may include a conductive material.

The wiring structure 680 may include a conductive line 685. The conductive line 685 may extend long in the second direction DR2. Furthermore, the plurality of conductive lines 685 each extend in the second direction DR2, and may be spaced apart from each other and arranged along the first direction DR1.

The conductive line 685 may be electrically connected to the plurality of channel structures CH arranged along the second direction DR2. For example, a channel contact 687 that extends in the third direction DR3 and connects the channel pad 636 and the conductive line 685 may be formed. The conductive line 685 may be connected to one end (e.g., the upper end) of the channel pattern 630 through the channel contact 687 and the channel pad 636. Such a conductive line 685 may be provided as a bit line of a semiconductor device according to some embodiments.

The first transistor TR1 and the second transistor TR2 of FIG. 1 may be electrically connected to the memory cells of FIG. 20. The first transistor TR1 and the second transistor TR2 of FIG. 1 may be disposed on the upper part or lower part of the memory cell of FIG. 20.

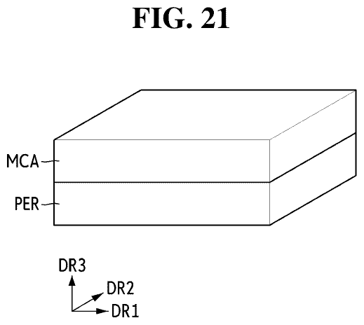

FIG. 21 is a diagram for explaining a semiconductor device according to some embodiments.

Referring to FIG. 21, the semiconductor device according to some embodiments may include a peripheral circuit structure PER and a memory cell structure MCA.

The memory cell structure MCA may be disposed on the peripheral circuit structure PER. In some embodiments, the memory cell structure MCA may be disposed above the peripheral circuit structure PER. In some embodiments, the memory cell structure MCA may be disposed below the peripheral circuit structure PER.

The peripheral circuit structure PER may include the semiconductor device described using FIG. 1, and the memory cell structure MCA may include the semiconductor device described using FIGS. 10 to 20. That is, the memory cell structure MCA may include the memory cells of the semiconductor device described using FIGS. 10 to 20, and the peripheral circuit structure PER may include the transistors TR1 and TR2 which are electrically connected to the memory cells of the memory cell structure MCA and described using FIG. 1.

According to embodiments of the present disclosure, there is provided a method for fabricating a semiconductor device including forming a ferroelectric material film on a substrate; forming a polysilicon film on the ferroelectric material film; performing an annealing process on the polysilicon film; removing the polysilicon film on which the annealing process has been performed to expose the ferroelectric material film; forming a gate insulating film on the exposed ferroelectric material film; and forming a gate electrode film on the gate insulating film.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor device comprising:
a substrate;
a ferroelectric material film on the substrate;
a gate insulating film on the ferroelectric material film; and
a gate electrode film on the gate insulating film,
wherein the gate electrode film is in contact with the gate insulating film.

2. The semiconductor device of claim 1, wherein the ferroelectric material film has an orthorhombic crystal structure.

3. The semiconductor device of claim 2, wherein the ferroelectric material film has a Pca21 space group.

4. The semiconductor device of claim 1, wherein the gate insulating film is in contact with the ferroelectric material film.

5. The semiconductor device of claim 1, further comprising:
an interfacial film between the substrate and the ferroelectric material film.

6. A semiconductor device comprising:
a substrate including a first region and a second region different from each other;
a first ferroelectric material film on the first region of the substrate;
a first gate insulating film on the first ferroelectric material film;
a first gate electrode film on the first gate insulating film;
a second ferroelectric material film on the second region of the substrate;
a second gate insulating film on the second ferroelectric material film; and
a second gate electrode film on the second gate insulating film,
wherein an upper side of the first gate electrode film is coplanar with an upper side of the second gate electrode film.

7. The semiconductor device of claim 6,
wherein the first region is a PMOS region, and the second region is an NMOS region.

8. The semiconductor device of claim 6,
wherein each of the first ferroelectric material film and the second ferroelectric material film has an orthorhombic crystal structure.

9. The semiconductor device of claim 8,
wherein the first ferroelectric material film and the second ferroelectric material film have a Pca21 space group.

10. The semiconductor device of claim 6,
wherein a thickness of the first ferroelectric material film is approximately the same as a thickness of the second ferroelectric material film.

11. The semiconductor device of claim 6, further comprising:
a first interfacial film between the substrate and the first ferroelectric material film; and
a second interfacial film between the substrate and the second ferroelectric material film.

12. The semiconductor device of claim 6,
wherein the first gate insulating film is between the first ferroelectric material film and the first gate electrode film, and
the second gate insulating film is between the second ferroelectric material film and the second gate electrode film.

13. The semiconductor device of claim 12,
wherein the first ferroelectric material film is in contact with the first gate insulating film, and
the second ferroelectric material film is in contact with the second gate insulating film.

14. The semiconductor device of claim 12,
wherein the first ferroelectric material film is in contact with the first gate electrode film, and
the second ferroelectric material film is in contact with the second gate electrode film.

15. A semiconductor device comprising:
a memory cell; and
a transistor electrically connected to the memory cell,
wherein the transistor includes a gate conductive film, a gate insulating film, and one ferroelectric material film, and
the one ferroelectric material film is disposed between the gate conductive film and the gate insulating film.

16. The semiconductor device of claim 15, wherein the memory cell is a non-volatile memory cell.

17. The semiconductor device of claim 15, wherein the memory cell is a volatile memory cell.

18. The semiconductor device of claim 15,
wherein the one ferroelectric material film has an orthorhombic crystal structure.

19. The semiconductor device of claim 15, further comprising:
a substrate including a cell region and a peripheral region,
wherein the memory cell is disposed on the cell region of the substrate, and
the transistor is disposed on the peripheral region of the substrate.

20. The semiconductor device of claim 15, further comprising:
a memory cell structure including the memory cell, and a peripheral circuit structure including the transistor,
wherein the peripheral circuit structure is disposed above or below the memory cell structure.
